(19) United States
(12) Patent Application Publication
(10) Pub. No.: US 2006/0044023 A1
(43) Pub. Date: Mar. 2, 2006

(54) Integrated circuit comparators and devices that compensate for reference voltage fluctuations

(76) Inventors: Jae-Cheol Yun, Seoul (KR); Seung-Bin You, Gyeonggi-do (KR); Min-Kyu Song, Gyeonggi-do (KR); Kyung-June Koh, Seoul (KR); Sang-Kyu Kim, Seoul (KR)

Correspondence Address: MYERS BIGEL SIBLEY & SAJOVEC, PO BOX 37428, RALEIGH, NC, 27627, US

(21) Appl. No.: 11/134,909

(22) Filed: May 23, 2005

(30) Foreign Application Priority Data
Aug. 25, 2004 (KR) 2004-66962

(51) Int. Cl. H03K 5/22

(52) U.S. Cl. 327/74

(57) ABSTRACT

An integrated circuit device includes a differential amplifier having first and second input terminals and at least one output terminal. The first input terminal is configured to receive a reference voltage and the second input terminal is configured to receive a time-varying input signal. A normally-on CMOS transmission gate is also provided. The CMOS transmission gate has an input terminal configured to receive a reference voltage and an output terminal electrically coupled to the first input terminal of the differential amplifier. This CMOS transmission gate operates to reduce fluctuations in the reference voltage caused by kick back noise by adding parasitic capacitance to the first input terminal of the differential amplifier.

Reference to Priority Application This application claims priority to Korean Patent Application No. 2004-66962, filed Aug. 25, 2004, the disclosure of which is hereby incorporated herein by reference.

### FIELD OF THE INVENTION

The present invention relates to integrated circuit devices and, more particularly, to integrated circuit devices that utilize reference voltages.

### BACKGROUND OF THE INVENTION

When an analog input signal and a reference voltage signal from a series of resistors are applied to a preamplifier of a comparator in an analog-to-digital converter (ADC), the reference voltage signal may fluctuate due to noise signals caused by variation of the input signals. The reference voltage should maintain a constant level regardless of variations of other signals so that the comparator may stably operate in a high speed ADC. Fluctuation of a reference voltage input to the comparator may cause large errors in performance.

In the prior art, capacitors have been inserted into reference voltage input terminals to keep the reference voltage level approximately constant. To do this, Metal-Insulator-Metal (MIM) capacitors or MOS capacitors have been used. In cases of using MIM capacitors or MOS capacitors inserted into the reference voltage input terminals of a comparator, a large portion of a chip area is necessary to secure capacitance required for high speed operation, due to small static capacitance per unit area of such capacitors. Accordingly, the size of the entire circuit may increase and the circuit layout may be complex.

### SUMMARY OF THE INVENTION

According to embodiments of the invention, a compensation circuit that compensates for fluctuations in a reference voltage includes a transmission gate for transmitting the reference voltage through the transmission gate; and an amplifier for amplifying a voltage difference between an input voltage and the reference voltage transmitted through transmission gate. The transmission gate maintains a turn-on status to enable the reference voltage to be transmitted through the transmission gate. The transmission gate may include a first control terminal coupled to a first DC voltage source and a second control terminal coupled to a second DC voltage source.

In another embodiments, a comparator includes a transmission gate for transmitting a reference voltage signal through the transmission gate and preamplifier for amplifying a voltage difference between an input voltage and the reference voltage transmitted through the transmission gate. A secondary amplifier is also provided for amplifying an output of the preamplifier. A comparison voltage generator is provided at an output. This voltage generator is configured to generate a first level output signal when the input voltage is higher than the reference voltage and generate a second level output signal when the input voltage is lower than the reference voltage.

In still other embodiments, a comparator includes a transmission gate for transmitting a reference voltage signal through the transmission gate and a CMOS preamplifier configured to amplify a voltage difference between an input voltage and the reference voltage transmitted through the transmission gate. The comparator may further include a secondary amplifier for amplifying an output of the CMOS preamplifier.

### BRIEF DESCRIPTION OF THE DRAWINGS

FIG. 1 is an electrical schematic of a conventional differential amplifier that is susceptible to kick back noise.

FIG. 2 is an electrical schematic of a compensation circuit according to an embodiment of the present invention.

FIG. 3 is an electrical schematic of a compensation circuit according to another embodiment of the present invention.

FIG. 4 is an electrical schematic of a CMOS transmission gate that may be used in the compensation circuits of FIGS. 2-3.

FIG. 5 is an electrical model of a MOS transistor within the CMOS transmission gate of FIG. 4, which shows parasitic capacitors between the transistor terminals.

FIG. 6 is a small signal equivalent circuit of the input transistor M2 in the conventional differential amplifier of FIG. 1.

FIG. 7 is a small signal equivalent circuit of the input transistor M2 in FIG. 2, which includes a parasitic capacitor representing a total parasitic capacitance of the transmission gate of FIG. 4.

FIG. 8 is a block diagram illustrating a comparator according to an embodiment of the present invention.

FIG. 9 is an electrical schematic of a conventional preamplifier with voltage divider.

FIG. 10 is an electrical schematic of a preamplifier with voltage divider and transmission gates, according to an embodiment of the present invention.

FIG. 11 is a graph illustrating differential input signals used in the compensation circuit of FIG. 3.

FIG. 12 is a graph illustrating reference voltage fluctuations before and after compensation for voltage fluctuation.

### DESCRIPTION OF THE EMBODIMENTS

Detailed illustrative embodiments of the present invention are disclosed herein. However, specific structural and functional details disclosed herein are merely representative for purposes of describing exemplary embodiments of the present invention. This invention, however, may be embodied in many alternate forms and should not be construed as limited to the embodiments set forth herein. Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures.

FIG. 1 is an electrical schematic of a conventional differential amplifier that is susceptible to kick back noise.

Referring to FIG. 1, the preamplifier includes, for example, diode-coupled PMOS transistors M3 and M4, NMOS transistors M1 and M2 having a common source configuration, and a constant current source Is.

An analog input signal Vin is applied to a gate of the transistor M1 with high speed, and an analog input signal Vref is applied to a gate of the transistor M2. For instance, the analog input signal Vin ranging from about 500 MHz to about 2 GHz in frequency may be applied to the gate of the transistor M1. The reference voltage signal Vref is, for example, a bias voltage generated by voltage dividing resistors.

The high-speed analog input signal Vin, inputted to an input terminal IN2, is passed through a parasitic capacitor between a gate and a source of the transistor M1, and is transferred to a node T. Then, the input signal Vin, through a parasitic capacitor between a gate and a source of the transistor M2, is transferred back to an input terminal IN1. As described, the input signal Vin affects the reference voltage signal Vref. This phenomenon is referred to as a kick back noise.

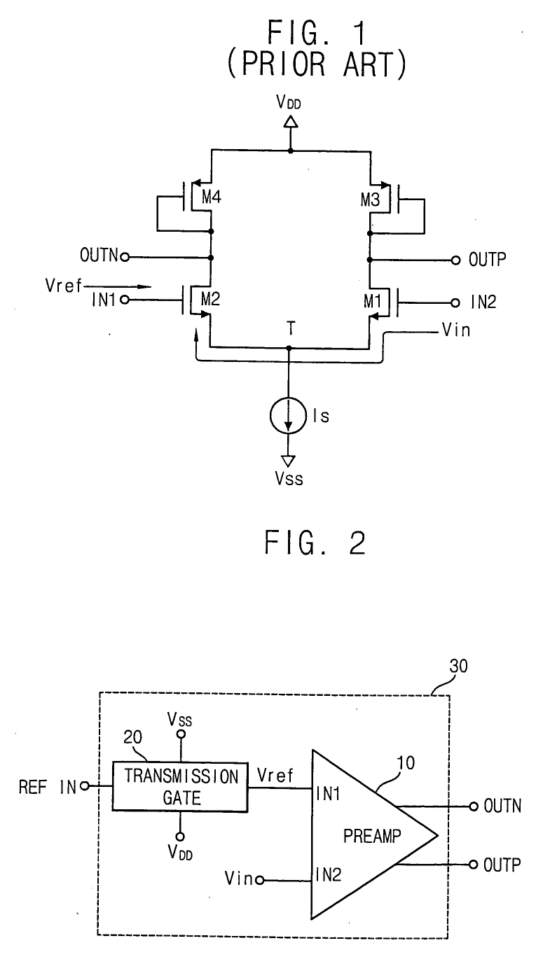

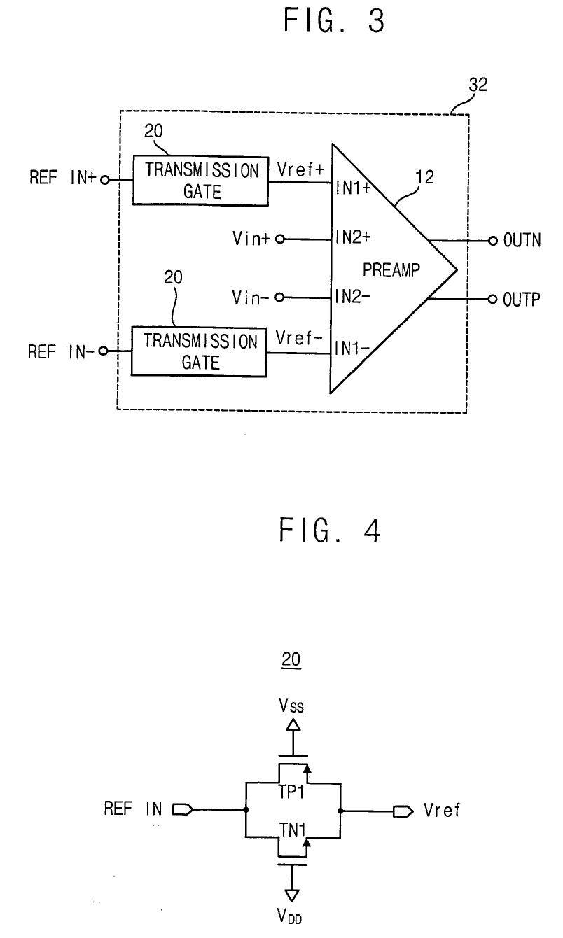

FIG. 2 is an electrical schematic of a compensation circuit according to an embodiment of the present invention. FIG. 3 is an electrical schematic of a compensation circuit according to another embodiment of the present invention. As illustrated by FIG. 2, a compensation circuit 30 includes a preamplifier 10 and a transmission gate (TG) 20. The transmission gate 20 is coupled to a reference voltage input terminal of the preamplifier 10, namely, a first input terminal IN1. The transmission gate 20 receives a first reference voltage signal REF IN and transfers the first reference voltage signal REF IN to the first input terminal IN1 of the preamplifier 10. The preamplifier 10 receives the reference voltage Vref, which is transmitted through the transmission gate 20, at the first input terminal IN1, and receives an analog input signal Vin at the second input terminal IN2. The preamplifier 10 differentially amplifies a difference between the reference voltage Vref and the input signal Vin and generates differential output signals OUTN and OUTP. The output signal OUTP is an inverted signal of the output signal OUTN. The preamplifier 10 may be implemented using the differential amplifier of FIG. 1.

Referring now to FIG. 3, a compensation circuit 32 for compensating for fluctuations in a reference voltage includes a preamplifier 12 and a pair of transmission gates 20. The preamplifier 12 receives differential input signals Vin+ and Vin−, respectively at input terminals IN2+ and IN2−, and receives differential reference voltages Vref+ and Vref−, which are passed respectively through the pair of transmission gates 20, to input terminals IN1+ and IN1−, and then outputs an output signal OUTN and an output signal OUTP. Each of the transmission gates 20 is respectively coupled to input terminals IN1+ and IN1− to thereby compensate for fluctuation in the reference voltages caused by kick back noise. The preamplifier circuit 12 may be implemented using a conventional differential amplifier.

FIG. 4 is an electrical schematic of a CMOS transmission gate that may be used in the compensation circuits of FIGS. 2-3. This transmission gate 20 includes a P type transistor TP 1 and an N type transistor TN1, which are connected in parallel. The P type transistor TP1 may be a PMOS transistor, and the N type transistor may be an NMOS transistor. The transmission gate 20, which is always turned on, operatively transfers the first reference voltage signal REF IN to the first input terminal IN1. A gate of the PMOS transistor TP1 may be connected to a first voltage source VSS, and a gate of the NMOS transistor TN1 may be connected to a second voltage source VDD so that the transmission gate 20 is always turned on. In particular, the second voltage source VDD is a positive DC voltage source and the first voltage source VSS is a ground voltage or a negative DC voltage source.

As for the first reference voltage signal REF IN applied to the transmission gate 20, the fluctuation of the voltage signal REF IN, which is affected by a parasitic parallel capacitance of the transmission gate 20, is reduced. Similarly, due to the existence of a parasitic parallel capacitance of the transmission gate 20, the fluctuation of the second reference voltage signal Vref, which is caused by the kick back noise from the input signal Vin, is also reduced. In particular, parasitic capacitances among a source terminal, a drain terminal, and a gate terminal of the transistors in the transmission gate 20 operatively compensate for fluctuations of the reference voltage signals. By adjusting a size ratio (W/L) of the transistors in the transmission gate 20, the size of the parasitic capacitance and the layout footprint of the transmission gate 20 may be regulated. Accordingly, the fluctuation of the reference voltage signal may be compensated in comparison with the conventional compensation method using conventional MIM capacitors or MOS capacitors.

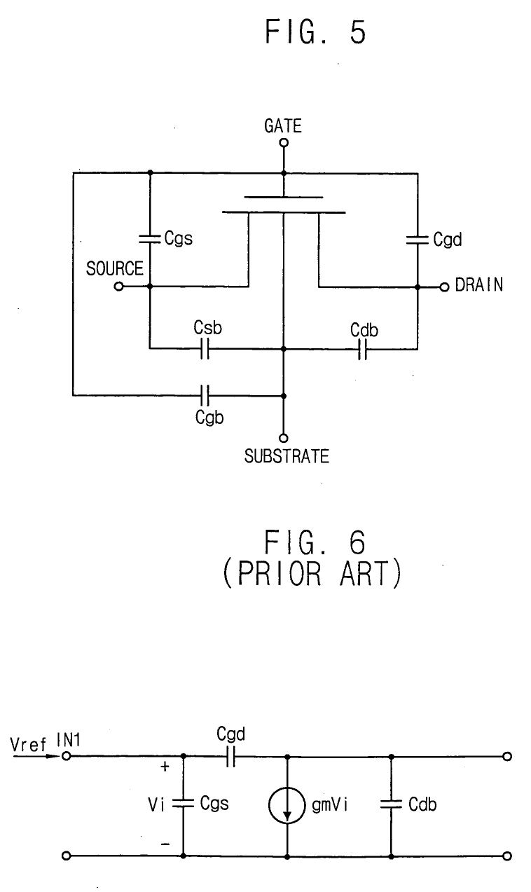

FIG. 5 is an electrical model of a MOS transistor within the CMOS transmission gate of FIG. 4, which shows parasitic capacitors between the transistor terminals. A sum of all capacitances among source, drain, and gate of the transistors in the transmission gate TG 20, namely a total capacitance CTG, may be approximated by formula (1).

$${C}_{TG} = \frac{Cgs \times Cg ⅆ}{Cgs + Cg ⅆ} + \frac{Csb \times C ⅆ b}{Csb + C ⅆ b} + Cgb \qquad ( 1 )$$

In formula (1), Cgs represents a parasitic capacitance between the gate and the source, Cgd represents a parasitic capacitance between the gate and the drain, Csb represents a parasitic capacitance between the source and a substrate (i.e. a body) of the transistor, Cdb represents a parasitic capacitance between the drain and the substrate, and Cgb represents a parasitic capacitance between the gate and the substrate.

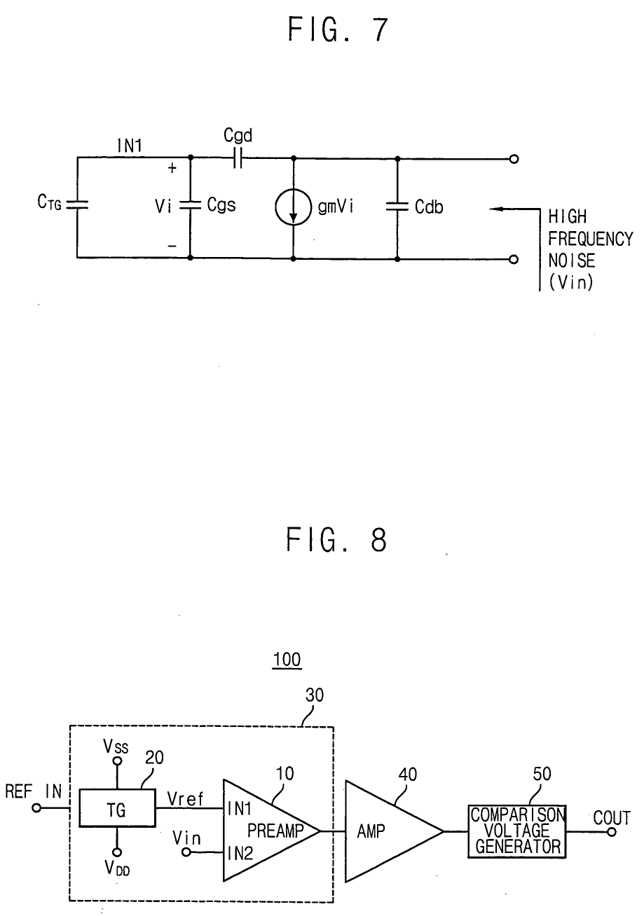

FIG. 6 is a small signal equivalent circuit of the input transistor M2 in the conventional differential amplifier of FIG. 1, and FIG. 7 is a small signal equivalent circuit of the input transistor M2 in FIG. 2, which includes a parasitic capacitor representing a total parasitic capacitance of the transmission gate of FIG. 4. Referring to FIG. 6, the transistor M2 is represented with a transconductance gm and the parasitic capacitances Cgs, Cgd, Cdb. As shown in FIG. 7, a capacitor corresponding to the total capacitance C_{TG}, is connected to the input terminal IN1 in parallel. The total capacitance C_{TG} at the input terminal IN1 is connected to the voltage sources VDD and VSS, which operate as AC ground, so that the total capacitance C_{TG} operates as a low pass filter at the input terminal IN1. This low pass filter cancels a high frequency component of the input signal Vin provided from a high frequency noise source. Therefore, the fluctuation of the reference voltage, caused by the input signal Vin operating as high frequency noise, may be reduced.

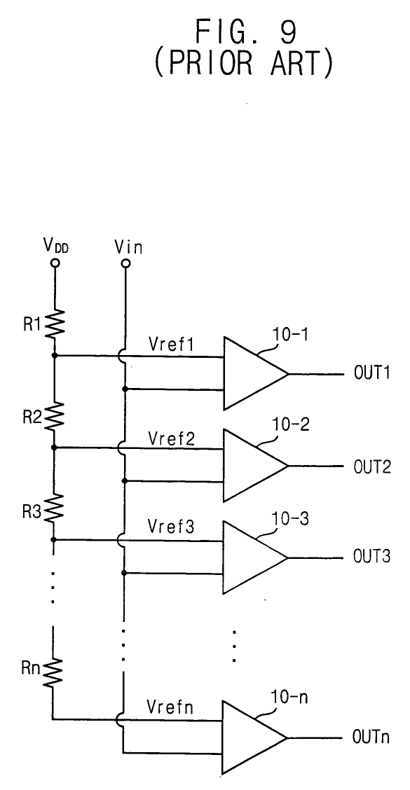

FIG. 8 is a block diagram illustrating a comparator using the transmission gate, according to another embodiment of the present invention. Referring to FIG. 8, a comparator 100 includes a compensation circuit 30, a secondary amplifier 40, and a comparison voltage generator 50. The compensation circuit 30 includes a transmission gate 20 and a preamplifier 10. To compensate for fluctuation of a reference voltage caused by kick back noise, the transmission gate 20 is coupled to a reference voltage input terminal of the preamplifier 10, namely, a first input terminal IN1. The preamplifier 10 receives a reference voltage Vref, which is transmitted through the transmission gate 20, at the first input terminal IN1, and receives an analog input signal Vin at the second input terminal IN2. The preamplifier 10 differentially amplifies a voltage difference between the reference voltage Vref and the input signal Vin.

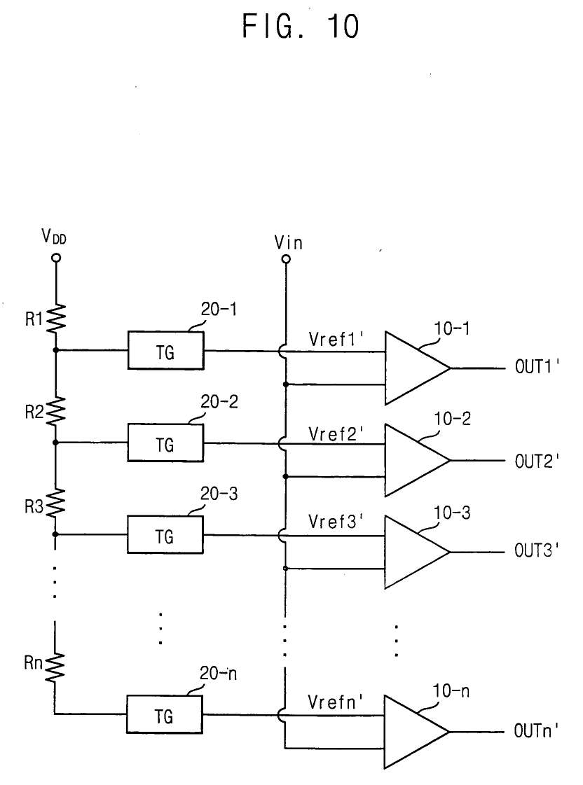

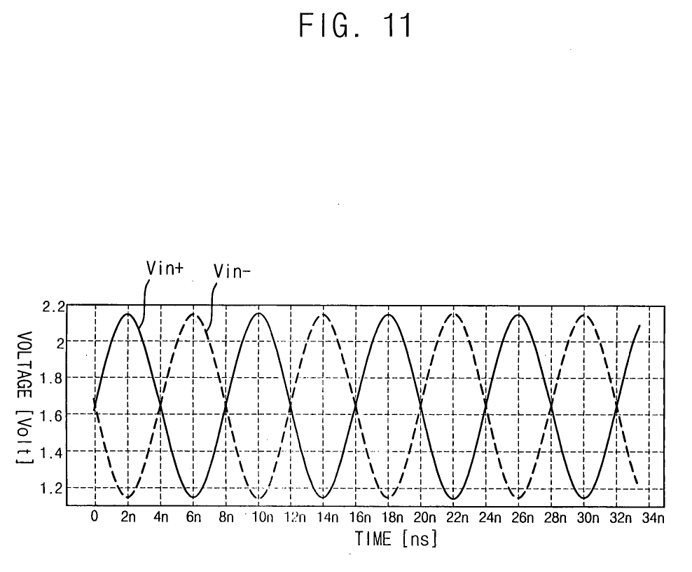

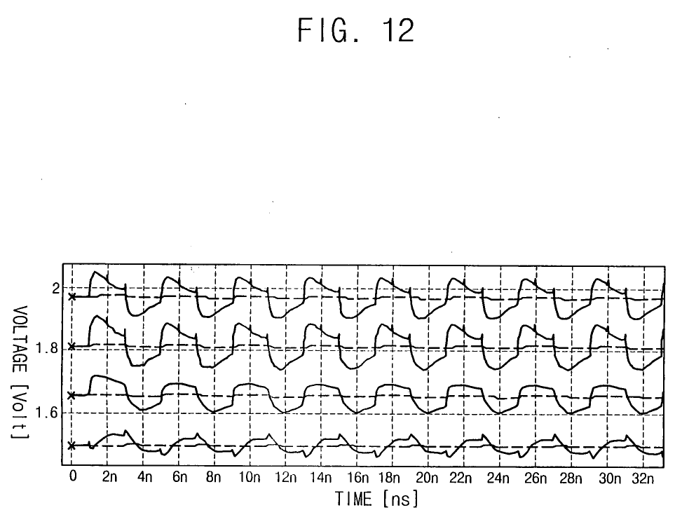

The secondary amplifier 40 amplifies an output signal of the preamplifier 10. The comparison voltage generator 50 receives the output of the secondary amplifier 40 and the reference voltage. The comparison voltage generator 50 outputs an output signal COUT with high level when the input signal Vin is higher than the reference voltage signal Vref, and outputs the output signal COUT with low level when the input signal Vin is lower than the reference voltage signal Vref. The comparison voltage generator 50 includes a latch circuit (not shown). For instance, in case the comparison voltage generator 50 includes a latch, the comparison voltage generator 50, in response to at least one clock signal, outputs the output signal COUT at a high level when the input signal Vin is higher than the reference voltage signal Vref, and outputs the output signal COUT at a low level when the input signal Vin is lower than the reference voltage signal Vref. The comparison voltage generator 50 may include two inverters connected in series. Accordingly, the comparator 100 receives the input signal Vin and the reference voltage signal Vref, so that the comparator 100 outputs an output signal COUT at a high level when the input signal Vin is higher than the reference voltage signal Vref, and outputs the output signal COUT at a low level when the input signal Vin is lower than the reference voltage signal Vref. FIG. 9 is an electrical schematic of a conventional preamplifier with voltage divider, and FIG. 10 is an electrical schematic of a preamplifier with voltage divider and transmission gates, according to an embodiment of the present invention. FIG. 11 is a graph illustrating differential input signals used in the compensation circuit of FIG. 3. FIG. 12 is a graph illustrating reference voltage fluctuations before and after compensation for voltage fluctuation.

Referring to FIG. 9, bias voltages (i.e. reference voltages) Vref1, Vref2, Vref3, . . . , and Vrefn, which are obtained through voltage resistors R1, R2, R3, . . . , and Rn of a voltage divider, are respectively inputted to respective first input terminals of preamplifiers, namely, a first preamplifier 10-1, a second preamplifier 10-2, a third preamplifier 10-3, . . . , and an n-th preamplifier 10-n. The input signal Vin is inputted to respective second input terminals of the preamplifiers 10-1, 10-2, . . . , and 10-n. The respective preamplifiers 10-1, 10-2, 10-3, . . . , and 10-n differentially amplify respective voltage differences between the respective reference voltage signals Vref1, Vref2, Vref3, . . . , and Vrefn and the respective input signals Vin, to thereby output respective output signals, namely, a first output signal OUT 1, a second output signal OUT2, a third output signal OUT3, . . . , and an n-th output signal OUTn.

Referring to FIG. 10, bias voltages (i.e. reference voltages) Vref1, Vref2, Vref3, . . . , and Vrefn, which are obtained through voltage dividing resistors R1, R2, R3, . . . , and Rn, are respectively inputted to respective input terminals of a first transmission gate 20-1, a second transmission gate 20-2, a third transmission gate 20-3, . . . , and an n-th transmission gate 20-n. The reference voltages Vref1′, Vref2′, Vref3′, . . . , and Vrefn′ are transferred through the transmission gates, namely, the first transmission gate 20-1, the second transmission gate 20-2, the third transmission gate 20-3, . . . , and the n-th transmission gate 20-n. The reference voltages are then input to respective first input terminals of preamplifiers, namely, a first preamplifier 10-1, a second preamplifier 10-2, a third preamplifier 10-3, . . . , and an n-th preamplifier 10-n. Input signal Vin is input to respective second input terminals of the preamplifiers 10-1, 10-2, 10-3, . . . , and 10-n. The respective preamplifiers 10-1, 10-2, 10-3, . . . , and 10-n differentially amplify respective voltage differences between the respective reference voltage signals Vref1′, Vref2′, Vref3′, . . . , and Vrefn′ and the respective input signals Vin, and output respective output signals, namely, a first output signal OUT 1′, a second output signal OUT2′, a third output signal OUT3′, . . . , and an n-th output signal OUTn′. In FIG. 10, the bias voltages (i.e. the reference voltages) Vref1, Vref2, Vref3, . . . , and Vrefn, and Vref1′, Vref2′, Vref3, . . . , and Vrefn′, generated by voltage dividing resistors, alternatively may be generated by a bias circuit implemented, for example, using multiple bias transistors (not shown).

The input signals Vin in FIG. 11 are sinusoidal waves of about 250 MHz frequency. In FIG. 12, the fluctuation of the reference voltages is respectively shown when the input signal Vin or an inverted signal of the input signal Vin is applied to a comparator. In detail, solid lines in FIG. 12 show simulation results for the fluctuation of four reference voltages selected among the reference voltages Vref1, Vref2, Vref3, . . . , and Vrefn, measured at each of the first input terminals of the preamplifiers 10-1, 10-2, 10-3, . . . , and 10-n in FIG. 9. However, dotted lines in FIG. 12 show simulation results for the fluctuation of four reference voltages selected among the reference voltages Vref1′, Vref2′, Vref3′, . . . , and Vrefn′, measured at each of the first input terminals of the preamplifiers 10-1, 10-2, 10-3, . . . , and 10-n in FIG. 10.

Referring to FIG. 12, the fluctuation level, about 70 mV, of the reference voltage signal, which is measured before the bias voltage compensation using transmission gates, is remarkably reduced to about 3 mV after the bias voltage compensation is provided according to embodiments of the invention. For precise performance of comparators, it is preferable that the fluctuation of a reference voltage be less than 1 LSB (i.e. Least Significant Bit). For instance, an 8-bit ADC, with resolving power 256 levels, has an input range of about 750 mV in order to get a LSB corresponding to about 3 mV. By using the transmission gate in accordance with the present invention, the fluctuation of the reference voltage was maintained within about 3 mV, that is, within 1 LSB. Although above exemplary embodiments discuss a preamplifier with a transmission gate (or transmission gates) used in an ADC, a circuit having a CMOS preamplifier(s) could also be applied to not only an ADC but also a DAC and other circuits.

According to the compensation circuit for compensating for the fluctuation of the reference voltage and the comparator using the compensation circuit, parasitic capacitances within a transmission gate that includes a pair of an NMOS transistor and a PMOS transistor are used for compensating for the fluctuation of the reference voltage, instead of MIM capacitors or MOS capacitors, which may be used at a reference voltage input terminal of a conventional comparator, so that the comparator may efficiently reduce the fluctuation of the reference voltage.

While the exemplary embodiments of the present invention and its advantages have been described in detail, it should be understood that various changes, substitutions and alterations can be made herein without departing from the scope of the invention as defined by appended claims.

What is claimed is:

1. An integrated circuit device, comprising:
a differential amplifier having first and second input terminals and at least one output terminal, said second input terminal configured to receive a time-varying input signal; and
a CMOS transmission gate having an input terminal configured to receive a reference voltage and an output terminal electrically coupled to the first input terminal of said differential amplifier.

2. The integrated circuit device of claim 1, wherein said CMOS transmission gate is a normally-on CMOS transmission gate.

3. The integrated circuit device of claim 2, wherein said CMOS transmission has a first gate terminal responsive to a power supply voltage and a second gate terminal responsive to a ground reference voltage.

4. The integrated circuit device of claim 1, wherein the time-varying input signal includes a time-varying component having a first frequency; and wherein said CMOS transmission gate is configured so that a parasitic capacitance between said CMOS transmission gate and the first input terminal of said differential amplifier operates as a low pass filter to a kick back signal transferred from the second input terminal to the first input terminal in response to the time-varying component having the first frequency.

5. An integrated circuit device, comprising:
a first differential amplifier having first and second input terminals and at least one output terminal, said second input terminal of said first differential amplifier configured to receive a time-varying input signal;
a second differential amplifier having first and second input terminals and at least one output terminal, said second input terminal of said second differential amplifier configured to receive the time-varying input signal;
a voltage divider comprising at least a first resistor having first and second terminals;
a first CMOS transmission gate having an input terminal electrically connected to the first terminal of the first resistor and an output terminal electrically connected to the first input terminal of said first differential amplifier; and
a second CMOS transmission gate having an input terminal electrically connected to the second terminal of the first resistor and an output terminal electrically connected to the first input terminal of said second differential amplifier.

6. The integrated circuit device of claim 5, wherein said first and second CMOS transmission gates are normally-on CMOS transmission gates.

7. A compensation circuit for compensating for a fluctuation of a reference voltage, comprising:
a transmission gate for transmitting the reference voltage through the transmission gate; and
an amplifier for amplifying a voltage difference between an input voltage and the reference voltage transmitted through the transmission gate.

8. The compensation circuit of claim 7, wherein the transmission gate maintains a turn-on status to enable the reference voltage to be transmitted through the transmission gate.

9. The compensation circuit of claim 7, wherein the transmission gate comprises a first selective terminal coupled to a first DC voltage source and a second selective terminal coupled to a second DC voltage source.

10. The compensation circuit of claim 7, wherein the transmission gate provides a reference voltage input terminal of the amplifier with the reference voltage.

11. The compensation circuit of claim 7, wherein the input voltage is in a range from about 500 MHz to about 2 GHz.

12. The compensation circuit of claim 7, wherein the transmission gate operates as a capacitor for reducing a kick back noise from the amplifier.

13. The compensation circuit of claim 7, wherein the amplifier comprises a CMOS amplifier.

14. The compensation circuit of claim 13, wherein the amplifier comprises
a differential amplifier including:
a first differential input for receiving the reference voltage, which is transmitted through the transmission gate; and
a second differential input for receiving the input voltage.

15. The compensation circuit of claim 14, wherein the amplifier comprises a differential amplifier, the differential amplifier including:
a first resistive element;
a second resistive element;
a first transistor, coupled to the first resistive element, for receiving the reference voltage transmitted through the transmission gate at a first control node of the third transistor; and
a second transistor, coupled to the second resistive element, for receiving the input voltage at a second control node of the second transistor.

16. The compensation circuit of claim 13, wherein the amplifier comprises a differential amplifier including:
a first input for receiving the reference voltage transmitted through the transmission gate;
a second input for receiving an inverted reference voltage, whereby the inverted reference voltage has the same magnitude as the reference voltage but an opposite sign;
a third input for receiving the input voltage; and
a fourth input for receiving an inverted input voltage, whereby the inverted input voltage has the same magnitude as the input voltage but an opposite sign.

17. A comparator comprising:
a transmission gate for transmitting a reference voltage through the transmission gate;
a preamplifier for amplifying a voltage difference between an input voltage and the reference voltage transmitted through the transmission gate;
a secondary amplifier for amplifying an output of the preamplifier; and
a comparison voltage generator configured to generate a first level output signal when the input voltage is higher than the reference voltage, and configured to generate a second level output signal when the input voltage is lower than the reference voltage.

18. The comparator of claim 17, wherein the transmission gate maintains a turn-on status to enable the reference voltage to be transmitted through the transmission gate.

19. The comparator of claim 17, wherein the transmission gate comprises a first selective terminal coupled to a first DC voltage source, and a second selective terminal coupled to a second DC voltage source.

20. The comparator of claim 17, wherein the amplifier comprises a CMOS amplifier.

21. The comparator of claim 20, wherein the amplifier comprises a differential amplifier including:
a first differential input for receiving the reference voltage transmitted through the transmission gate; and
a second differential input for receiving the input voltage.

22. A comparator comprising:
a transmission gate for transmitting a reference voltage through the transmission gate; and
a CMOS preamplifier configured to amplify a voltage difference between an input voltage and the reference voltage transmitted through the transmission gate.

23. The comparator of claim 22, wherein the comparator further comprises a secondary amplifier for amplifying an output of the CMOS preamplifier.

24. The comparator of claim 22, wherein the transmission gate maintains a turn-on status to enable the reference voltage to be transmitted through the transmission gate.

25. The comparator of claim 22, wherein the transmission gate comprises a first selective terminal coupled to a first DC voltage source and a second selective terminal coupled to a second DC voltage source.

26. The comparator of claim 22, wherein the transmission gate comprises
a PMOS transistor having a first control node, the first control node being coupled to a first DC voltage source; and
an NMOS transistor having a second control node, the second control node being coupled to a second DC voltage source.
